(19) United States
(12) Patent Application Publication
(10) Pub. No.: US 2026/0005068 A1
(43) Pub. Date: Jan. 1, 2026

(54) MODIFIED ETCH STOP LAYERS FOR FORMING GATE VIAS

(71) Applicant: Taiwan Semiconductor Manufacturing Company, Ltd., Hsin-Chu (TW)

(72) Inventors: Guang-Hong Zheng, Hsinchu City (TW); Yuan-Tien Tu, Puzih City (TW); Chih-Yuan Ting, Taipei City (TW); Chao-Cheng Chen, Hsin-Chu City (TW); Yi-Chen Wang, Hsinchu (TW); Fang-Yu Lin, Miaoli County (TW); Sheng-Liang Pan, Hsin-Chu (TW); Guan-Xuan Chen, Taoyuan (TW); Chia Lin Yeh, New Taipei City (TW)

(21) Appl. No.: 18/757,898

(22) Filed: Jun. 28, 2024

(51) Int. Cl. H01L 21/768; H01L 21/8234; H01L 23/522; H01L 27/088; H01L 29/08

(52) U.S. Cl. CPC H01L 21/76832; H01L 21/76826; H01L 21/76871; H01L 21/76877; H01L 23/5226; H10D 62/151; H10D 84/0149; H10D 84/038; H10D 84/83

(57) ABSTRACT

One aspect of the present disclosure pertains to a semiconductor device. The semiconductor device includes a source/drain (S/D) contact over an S/D feature; a gate structure over a channel region, where the channel region is adjacent the S/D feature; a first interlayer dielectric (ILD) layer over the gate structure and surrounding the S/D contact; an etch stop layer over the first ILD layer and the S/D contact, where the etch stop layer includes a first portion and a second portion, and the second portion is different from the first portion in chemical composition; a second ILD layer over the etch stop layer; and a gate via over the gate structure, where the gate via is surrounded by the second portion of the etch stop layer.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

As technology nodes become smaller, there is an increased risk of unwanted coupling between semiconductor device components. For example, gate to source/drain leakage may be caused by gate vias getting too close to source/drain contacts due to over-etching effects when forming the gate vias. Gate vias are formed by forming gate via trenches and filling a conductive material in the gate via trenches. However, the gate via trenches require a deeper etch compared to forming source/drain via trenches, and the deeper etch requires etching through multiple dielectric layers of different materials. For these reasons, over-etching effects such as unintended lateral etch may cause bowing effects and damage to the trench sidewalls. As such, when the gate vias are filled in the gate via trenches, the gate vias may be too close to the source/drain contacts, thereby causing undesired leakage effects.

Therefore, although existing methods and structures for forming gate vias have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion. It is also emphasized that the figures appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates a semiconductor device having a gate via surrounded by a modified etch stop layer, according to an embodiment of the present disclosure.

FIG. 2 illustrates a flow chart of a method to form a semiconductor device having a gate via surrounded by a modified etch stop layer, in portion or in entirety, according to an embodiment of the present disclosure.

FIGS. 3-11 illustrate cross-sectional views of a semiconductor device at intermediate stages of fabrication and processed in accordance with the method of FIG. 2, according to an embodiment of the present disclosure.

FIG. 12 illustrates a semiconductor device having modified etch stop layers surrounding gate via(s) and surrounding butted contact(s), according to an embodiment of the present disclosure.

FIG. 13 illustrates a top view of a semiconductor device having modified etch stop layers surrounding a gate via and a butted contact, according to an embodiment of the present disclosure.

FIG. 14 illustrates a flow chart of a method to form a semiconductor device having modified etch stop layers surrounding gate via(s) and surrounding butted contact(s), in portion or in entirety, according to an embodiment of the present disclosure.

FIGS. 15-24 illustrate cross-sectional and top views of a semiconductor device at intermediate stages of fabrication and processed in accordance with the method of FIG. 14, according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself limit the relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” “substantially,” and the like, the term is intended to encompass numbers that are within a reasonable range including the number described, such as within +/−10% of the number described or other values as understood by person skilled in the art. For example, the term “about 5 nm” may encompass the dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” and the like, may be understood to be within +/−10% between the compared features. Further, disclosed dimensions of the different features can implicitly disclose dimension ratios between the different features.

The present disclosure relates to semiconductor devices having gate vias surrounded by modified etch stop layers. The modified etch stop layers act as sidewall buffers that prevent over-etching effects such as unintended lateral etch when forming gate via trenches. Without the modified etch stop layers, sidewalls of the gate via trenches may be damaged or laterally over-etched. If laterally over-etched, the later-formed gate vias will get too close to adjacent contacts such as source/drain contacts. As such, the gate vias may short or cause leakage effects to source/drain features. To address such shorting and leakage effects, the present disclosure provides a method of forming modified etch stop layers and semiconductor devices having the modified etch stop layers.

The modified etch stop layers prevent lateral over-etch during the formation of gate vias. These modified etch stop layers may be selectively formed for gate vias but not for source/drain vias. This is because there is less lateral over-etch issues when forming source/drain vias when compared to forming gate vias. Compared to gate vias, source/drain vias require a smaller etch depth and less dielectric layer layers to etch through. As such, the modified etch stop layers may not be necessary for the source/drain vias. For semiconductor devices that have butted contacts, the modified etch stop layers may be formed only on a portion of the butted contacts. A butted contact (also known as a gate-to-drain contact) is configured as a combination of a gate via and a source/drain via. In these cases, the modified etch stop layers may only be necessary for the gate via portion of the butted contact but not the source/drain via portion of the butted contacts. By selectively forming the modified etch stop layers to target the gate vias or gate via portions, leakage issues are addressed while avoiding the extra costs of forming unnecessary layers.

To illustrate the various aspects of the present disclosure, methods of forming a semiconductor device are discussed below. Embodiments shown in the present disclosure are implemented with Gate-All-Around (GAA) field effect transistors (FETs), but the present disclosure is not limited thereto. GAA FETs refer to transistors having gate stacks (gate electrodes and gate dielectric layers) surrounding transistor channels, such as vertically-stacked gate-all-around horizontal nanowire or nanosheet MOSFET devices. Those of ordinary skill in the art should appreciate that they may readily use the present disclosure as a basis for designing or modifying other structures for carrying out the same purposes and/or achieving the same advantages of the embodiments introduced herein. For example, the present disclosure may also be implemented with fin FETs.

In the following description, semiconductor devices may also be referred to as semiconductor structures that correspond to the semiconductor devices. Further, the modified etch stop layer(s) described herein may also be referred to as simply a modified layer, a modified dielectric layer, a modification layer, a buffer layer, a modified etch stop sidewall layer, or the like. Although described as a modified “etch stop layer”, the present disclosure contemplates that such a layer can simply be a dielectric layer and is not limited to being an “etch stop layer.”

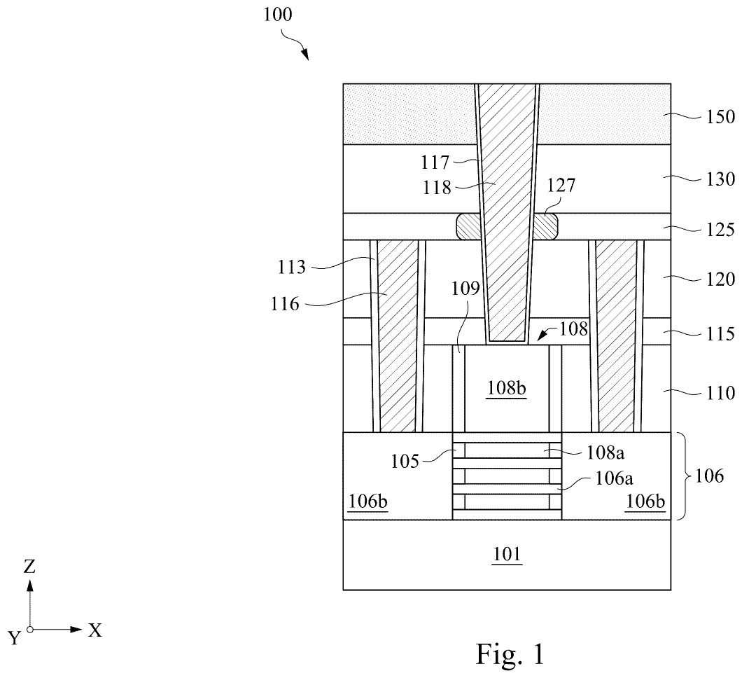

FIG. 1 illustrates a semiconductor device 100 having a gate via 118 surrounded by a modified etch stop layer 127, according to an embodiment of the present disclosure. The semiconductor device 100 may be a portion of an integrated circuit (IC) chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. In some embodiments, the device is included in a non-volatile memory, such as a non-volatile random access memory (NVRAM), a flash memory, an electrically erasable programmable read only memory (EEPROM), an electrically programmable read-only memory (EPROM), other suitable memory type, or combinations thereof.

The semiconductor device 100 includes a substrate 101 and an active region 106 over and protruding from the substrate 101. The substrate 101 may be a silicon (Si) substrate, or a substrate having other semiconductor materials such as germanium (Ge), silicon carbide (SiC), silicon germanium (SiGe), or diamond. The active region 106 extends lengthwise along the X direction and may protrude above an isolation structure (not shown) also disposed over the substrate 101. The isolation structure may be a shallow trench isolation (STI) layer and provides isolation between adjacent active regions 106 spaced along the Y direction (not shown). The dielectric material for the isolation structure may include silicon oxide, silicon oxynitride, fluorine-doped silicate glass (FSG), a low-k dielectric, combinations thereof, and/or other suitable materials.

The active region 106 includes channel regions between source/drain (S/D) regions. The channel regions may include vertically stacked channels 106a, the S/D regions may include S/D epitaxial features 106b, and the channels 106a laterally extend between the S/D epitaxial features 106b along the X direction. The S/D epitaxial features 106b may include n-type S/D features that correspond with n-type GAA transistor regions or p-type source/drain features that correspond with p-type GAA transistor regions. The S/D epitaxial features 106b may be formed by an epitaxy process using CVD deposition techniques (for example, VPE and/or UHV-CVD), molecular beam epitaxy, other suitable epitaxial growth processes, or combinations thereof. The S/D epitaxial features 106b are doped with n-type dopants and/or p-type dopants. In some embodiments, for the n-type GAA transistors, S/D epitaxial features 106b include silicon and can be doped with carbon, phosphorous, arsenic, other n-type dopant, or combinations thereof (for example, forming Si:C epitaxial source/drain features, Si:P epitaxial source/drain features, or Si:C:P epitaxial source/drain features). In some embodiments, for the p-type GAA transistors, S/D epitaxial features 106b include silicon germanium or germanium and can be doped with boron, other p-type dopant, or combinations thereof (for example, forming Si:Ge:B epitaxial source/drain features).

Still referring to FIG. 1, the semiconductor device 100 includes a gate structure 108 (or gate stack) disposed over the channel region of the active region 106. The gate structure 108 engages and wraps around each of the channels 106a. The gate structure 108 includes a gate dielectric layer (not explicitly shown) and a gate electrode (not explicitly shown) disposed on the gate dielectric layer. In some embodiments, the gate dielectric layer includes an interfacial layer and a high-k dielectric layer disposed on the interfacial layer. The gate electrode may include one or more conductive materials, such as a capping layer, a work function metal layer, a blocking layer, a metal fill layer, and/or other proper conductive material layers. The work function layers (if present) may be same or different and may be an n-type work function layer or a p-type work function layer, depending on the types of the corresponding GAA transistors. The gate dielectric layer includes a high-k dielectric material, such as materials having a dielectric constant greater than silicon oxide (k≈3.9). The metal fill layer includes a suitable conductive material, such as Al, W, and/or Cu. The metal fill layer may additionally or collectively include other metals, metal oxides, metal nitrides, other suitable materials, or combinations thereof.

Still referring to FIG. 1, the gate structure 108 includes a bottom portion 108a disposed below the topmost channel 106a and a top portion 108b disposed over the topmost channel 106a. Inner spacers 105 are disposed along sidewalls of the bottom portion 108a of the gate structure 108 and gate spacers 109 are disposed along sidewalls of the top portion 108b of the gate structure 108. Each of the inner spacers are disposed vertically between channels 106a and laterally between the S/D epitaxial feature 106b and the gate structure 108. Each of the gate spacers 109 land on the topmost channel 106a and may be disposed directly above the inner spacers 105. In some embodiments, the inner spacers 105 include a dielectric material that includes silicon, oxygen, carbon, nitrogen, other suitable material, or combinations thereof (for example, silicon oxide (SiO₂), silicon nitride (SiN), silicon oxynitride (SiON), silicon carbide (SiC), or silicon oxycarbonitride (SiOCN). In some embodiments, the inner spacers 105 includes a low-k dielectric material. In some embodiments, the gate spacers 109 may be made of silicon oxide (SiO₂), silicon nitride (SiN), silicon oxycarbide (SiOC), silicon oxycarbonitride (SiOCN), silicon carbonitride (SiCN), metal nitride, or a suitable dielectric material. In some embodiments, the inner spacers 105 may include a material that is different from a material of the gate spacers 109 to achieve desired etching selectivity or to achieve different isolation effects.

Still referring to FIG. 1, the semiconductor device 100 includes an interlayer dielectric (ILD) layer 110 over the S/D epitaxial features 106b. The ILD layer 110 also laterally surrounds the top portion 108b of the gate structure 108. As shown, the gate spacers 109 are disposed laterally between the ILD layer 110 and the top portion 108b of the gate structure 108. In the present embodiment, the ILD layer 110 includes an oxide-based dielectric material such as silicon oxide (SiO₂). However, the ILD layer 110 can include a multilayer structure having multiple dielectric materials. In some embodiments, a contact etch stop layer (CESL) (not shown) is disposed vertically between the S/D epitaxial features 106b and the ILD layer 110 and laterally between and the gate spacers 109 and the ILD layer 110. The CESL includes a material different than ILD layer 110, such as a dielectric material that is different than the dielectric material of ILD layer 110. For example, where ILD layer 110 includes a low-k oxide-based dielectric material, the CESL includes silicon and nitrogen, such as silicon nitride (SiN) or silicon oxynitride (SiON).

Still referring to FIG. 1, the semiconductor device 100 includes a CESL 115 disposed over the ILD layer 110 and the gate structure 108, an ILD layer 120 disposed over the CESL 115, a CESL 125 disposed over the ILD layer 120, an ILD layer 130 disposed over the CESL 125, and a hard mask layer 150 disposed over the ILD layer 130. Further, the CESL 125 includes a modified etch stop layer 127 that surrounds the gate via 118. As explained in greater detail below, the modified etch stop layer 127 has a greater oxygen concentration than the rest of the CESL 125 to act as a protection layer against lateral over-etch when forming the gate via 118. The modified etch stop layer 127 is a buffer layer laterally disposed between the gate via 118 and the rest of the CESL 125 along the X direction. As shown, the remaining portions of the CESL 125 are laterally distanced from the gate via 118 by a width of the modified etch stop layer 127 along the X direction. Further, the modified etch stop layer 127 and the rest of the CESL 125 may share a common top and a common bottom surface. In an embodiment, the top surfaces of the modified etch stop layer 127 and the rest of the CESL 125 are substantially coplanar. In an embodiment, the bottom surfaces of the modified etch stop layer 127 and the rest of the CESL 125 are substantially coplanar. In the present embodiments, the ILD layers 110, 120, and 130 include different dielectric materials from the CESLs 115 and 125. For example, the ILD layers 110, 120, and 130 are made of an oxide-based dielectric such as silicon oxide and the CESLs 115 and 125 are made of a nitride-based dielectric such as silicon nitride. This allows for etchant selectivity when forming various conductive plugs, vias, and contacts through the different ILD and CESL layers.

Still referring to FIG. 1, the hard mask layer 150 is made of a different material from the ILD layers 110, 120, and 130. For example, the hard mask layer 150 may be made of materials comprising silicon (Si), silicon nitride (SiN), silicon carbide (SiC), tungsten carbide (WC), or a metal nitride. As described in further details below, the hard mask layer 150 provides masking protection when performing a plasma treatment 300 to modify the CESL 125 and to remove photoresist layers. The present disclosure contemplates that the hard mask layer 150 may be present in the final structure or it may be removed through a planarization process that also removes portions of the gate via 118. If present in the final structure, the hard mask layer 150 is a dielectric layer such as silicon nitride. If not present in the final structure, the hard mask layer could be a dielectric layer or a metal-containing layer such as tungsten carbide (WC) or a metal nitride.

Still referring to FIG. 1, the semiconductor device 100 incudes S/D contacts 116 that penetrate through the ILD layer 120, the CESL 115, and the ILD layer 110 to land on the S/D epitaxial features 106b. The S/D contacts 116 features may include silicide features and metal fill layers over the silicide features. The silicide features may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. The metal fill layer over the silicide features may include titanium (Ti), titanium nitride (TiN), ruthenium (Ru), copper (Cu), nickel (Ni), cobalt (Co), tungsten (W), tantalum (Ta), or molybdenum (Mo). In the present embodiments, the S/D contacts 116 include tungsten (W). Further, the S/D contacts 116 may be lined with barrier layers 113 to prevent metal diffusion into surrounding environment. The barrier layers 113 may include Ti/TiN, SiN, or W. In the present embodiment, the barrier layers 113 include SiN.

Still referring to FIG. 1, the semiconductor device 100 incudes a gate via 118 that penetrates through the hard mask layer 150, the ILD layer 130, the CESL 125 (or modified portions thereof), the ILD layer 120, and the CESL 115 to land on the gate structure 108. The gate via 118 may include conductive materials such as W, Ti/TiN, or Ru. In the present embodiments, the gate via 118 includes tungsten (W). Further, the gate via 118 may be lined with a conformal seed layer 117 that surrounds the gate via 118. The conformal seed layer 117 acts as an adhesion layer to facilitate better meal fill when forming the gate via 118. The conformal seed layer 117 may also prevent metal diffusion into surrounding environment. The conformal seed layer 117 may include Ti/TiN or W. In the present embodiment, the conformal seed layer 117 includes TiN or W. As shown, the gate via 118 penetrates through the modified etch stop layer 127 of the CESL 125.

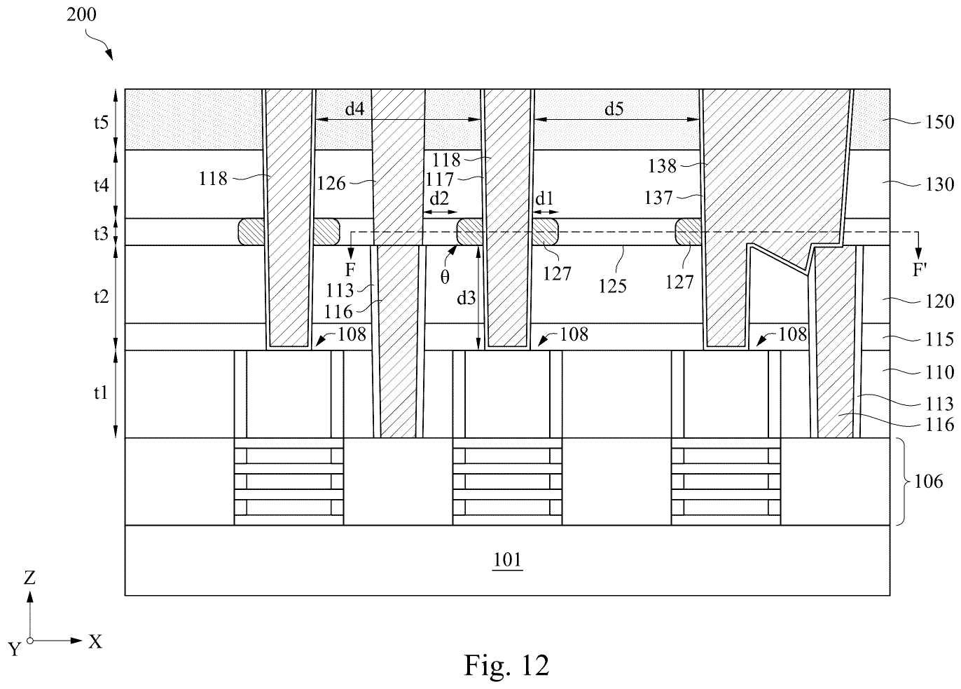

Although not shown in FIG. 1, but shown in FIG. 12, the semiconductor device 100 may further include S/D vias 126 that penetrates through the hard mask layer 150, the ILD layer 130, and the CESL 125 to land on the S/D contacts 116. These S/D vias 126 include similar materials as the gate via 118. However, as explained in more detail below, these S/D vias 126 do not penetrate through any modified etch stop layer 127 and they also may be free of any conformal seed layers.

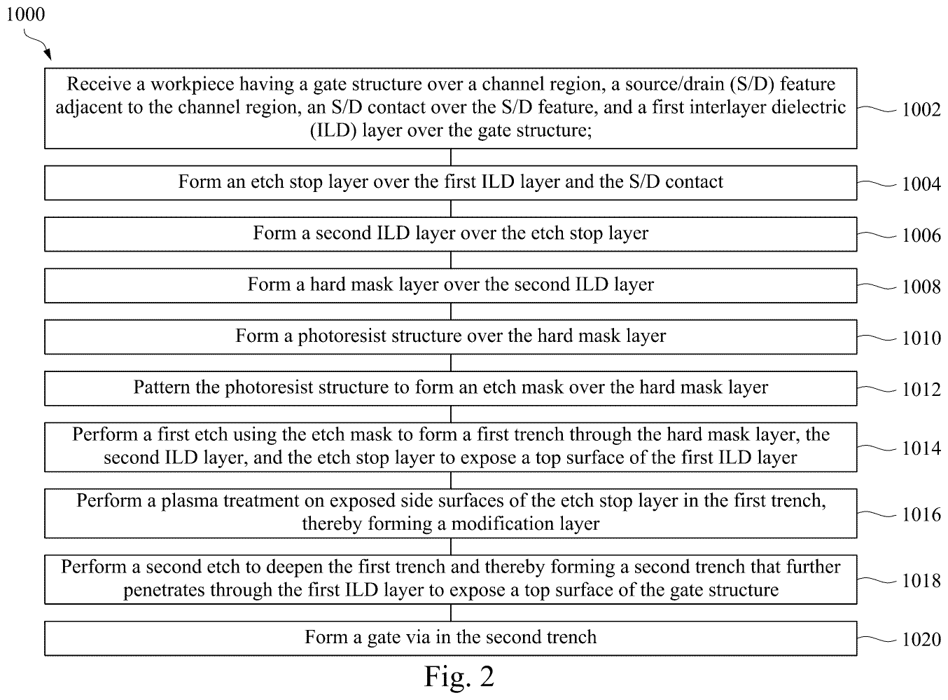

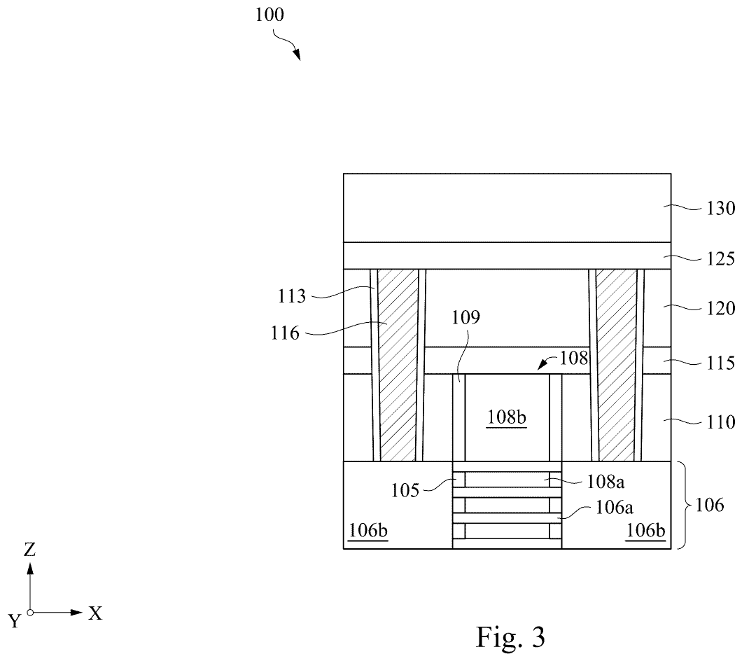

FIG. 2 illustrates a flow chart of a method 1000 to form a semiconductor device 100 having a gate via 118 surrounded by a modified etch stop layer 127, in portion or in entirety, according to an embodiment of the present disclosure. FIGS. 3-11 illustrate cross-sectional views of a semiconductor device 100 at intermediate stages of fabrication and processed in accordance with the method 1000 of FIG. 2. The method 1000 is described below with reference to FIGS. 3-11. Features already described with respect to FIG. 1 may correspond to features referenced in FIGS. 3-11. However, some of the same or similar features are further described with additional details, while some of the same or similar features will not be described again for the sake of brevity.

Referring now to FIG. 3, the method 1000 at operation 1002 receives a workpiece having a gate structure 108 over channels 106a of a channel region. The workpiece further includes a source/drain (S/D) feature (e.g., an S/D epitaxial feature 106b) adjacent to the channel region, an S/D contact 116 over the S/D feature, and a first interlayer dielectric (ILD) layer (e.g., ILD layer 120) over the gate structure 108. The first ILD layer may refer to the ILD layer 120 or it may refer to the CESL 115 and the ILD layer 120 collectively.

Still referring to FIG. 3, the method 1000 at operation 1004 forms an etch stop layer (e.g., CESL 125) over the first ILD layer (e.g., the ILD layer 120) and the S/D contact (e.g., an S/D epitaxial feature 106b). The etch stop layer may be formed by any suitable deposition process (such as CVD, PVD, ALD, HDPCVD, MOCVD, RPCVD, PECVD, LPCVD, ALCVD, APCVD, plating, other suitable methods, or combinations thereof). In the present embodiment, the etch stop layer is a silicon nitride layer (SiN) or a silicon carbonitride layer (SiCN). In some embodiments, the etch stop layer is a low density dielectric layer. For example, the etch stop layer (e.g., CESL 125) may have a lower density than the CESL 115 and the hard mask layer 150 due to the presence of carbon. A lower density layer and/or an etch stop layer having carbon may better facilitate the later plasma treatment process 300 for oxygenating the etch stop layer, which then forms the modified etch stop layer 127.

Still referring to FIG. 3, the method 1000 at operation 1006 forms a second ILD layer (e.g., ILD layer 130) over the etch stop layer (e.g., CESL 125). The second ILD layer may be formed by any suitable deposition process (such as CVD, PVD, ALD, HDPCVD, MOCVD, RPCVD, PECVD, LPCVD, ALCVD, APCVD, plating, other suitable methods, or combinations thereof). The second ILD layer includes similar materials as the first ILD layer (e.g., both ILD layers includes silicon oxide).

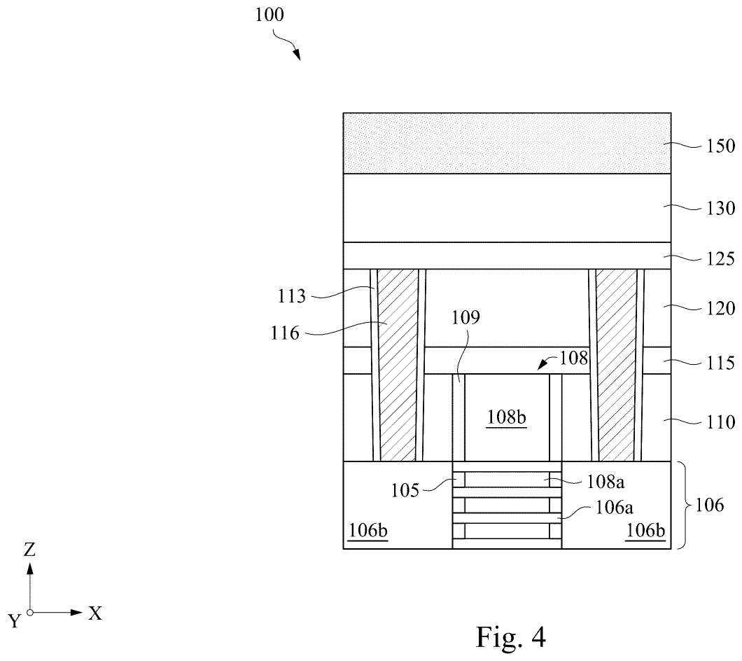

Now referring to FIG. 4, the method 1000 at operation 1008 forms a hard mask layer 150 over the second ILD layer (e.g., ILD layer 130). The hard mask layer 150 may be formed by any suitable deposition process (such as CVD, PVD, ALD, HDPCVD, MOCVD, RPCVD, PECVD, LPCVD, ALCVD, APCVD, plating, other suitable methods, or combinations thereof). In some embodiments, the hard mask layer 150 is a high density dielectric or metal layer. In an embodiment, the hard mask layer 150 includes silicon nitride, the etch stop layer (e.g., CESL 125) also includes silicon nitride, but the hard mask layer 150 has a greater density than the etch stop layer. A higher density layer may better facilitate the later plasma treatment process 300 by selectively blocking oxygen plasma when oxygenating the etch stop layer. In an embodiment, both the hard mask layer 150 and the etch stop layer include silicon nitride, but the etch stop layer includes carbon while the hard mask layer does not. In an embodiment, the hard mask layer also includes carbon, but at a smaller concentration than that of the etch stop layer. For example, the hard mask layer has less than 5% carbon by atomic percent while the etch stop layer has about 20% or more carbon by atomic percent.

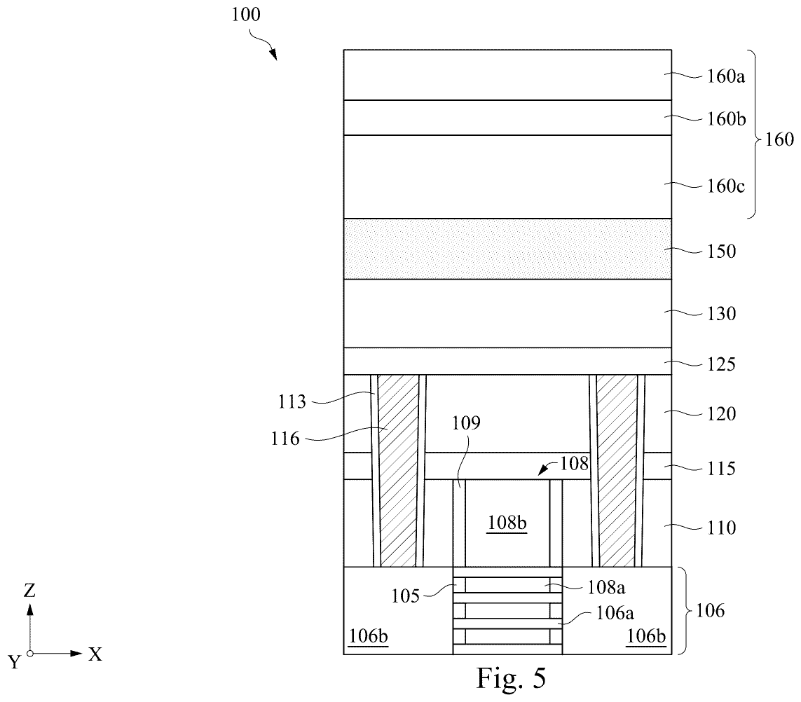

Now referring to FIG. 5, the method 1000 at operation 1010 forms a photoresist structure 160 over the hard mask layer 150. In the embodiment shown, the photoresist structure 160 is a tri-layer photoresist stack having a top layer 160a, a middle layer 160b, and a bottom layer 160c. The top layer 160a may be a photoresist (PR) layer sensitive to light exposure. The middle layer 160b may be an anti-reflective layer to aid in the exposure and focus when patterning the top layer 160a. The middle layer 160b may be a silicon-containing intermediate layer (e.g., spin-on-glass) layer. In an embodiment, the middle layer 160b includes silicon and oxygen. The bottom layer 160c may be an organic film underlayer to provide further anti-reflective properties but also to provide etch-durable properties when using the later-formed patterned top layer 160a as an etch mask. The bottom layer 160c may include carbon, nitrogen, hydrogen, and/or, oxygen but is free of silicon.

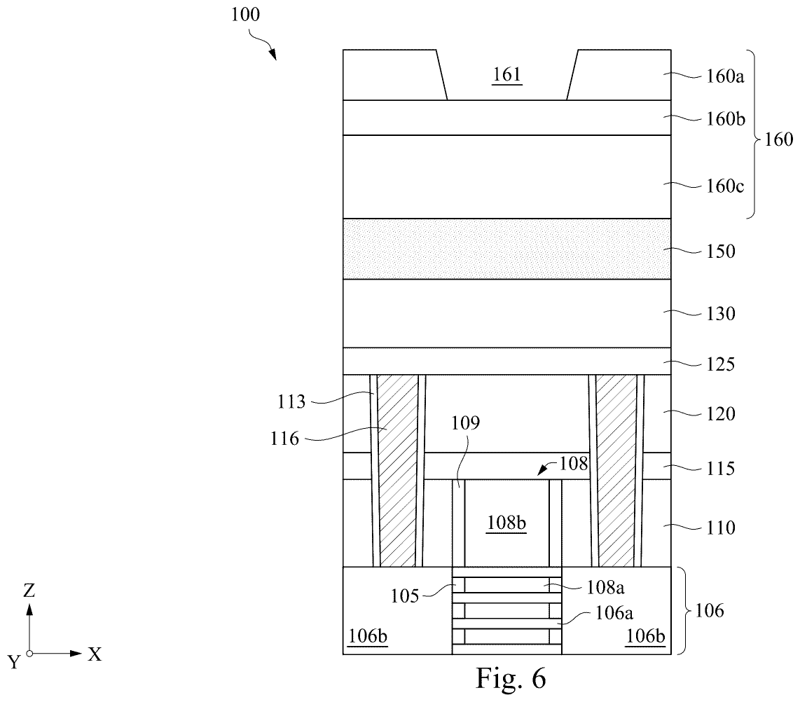

Now referring to FIGS. 6, the method 1000 at operation 1012 patterns the photoresist structure 160 to form an etch mask over the hard mask layer. To form the etch mask, the top layer 160a is patterned by first exposing the top layer 160a to radiation such as light or an excimer laser through a photomask that defines an opening 161. Then, a bake or cure operation is performed to harden the resist in the top layer 160a. Then, a developer is used to remove either the exposed or unexposed portions of the resist, depending on whether a positive resist or a negative resist is used, to form the pattern in the top layer 160a. As a result, the opening 161 is formed in the top layer 160a.

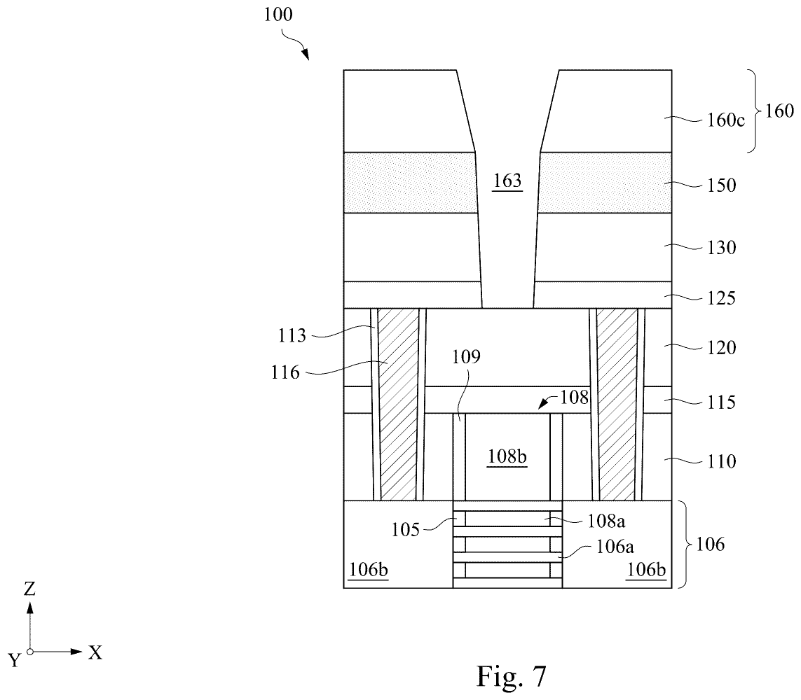

Now referring to FIG. 7, the method 1000 at operation 1014 performs a first etch using the etch mask to form a first trench 163 through the hard mask layer 150, the second ILD layer (e.g., ILD layer 130), and the etch stop layer (e.g., CESL 125) to expose a top surface of the first ILD layer (e.g., ILD layer 120). During this first etch, the photoresist structure 160 may also be etched. In the embodiment shown, after the first etch, the top layer 160a and the middle layer 160b are both fully removed, while the bottom layer 160c is only partially removed. This is because the bottom layer 160c is configured with etch-durable properties and may also be formed thicker than the top and middle layers 160a and 160b. As such, while the top and middle layers 160a and 160b may be etched away during the first etch, the bottom layer 160c continues to act as an etch mask for patterning the underlying layers (i.e., hard mask layer 150, ILD layer 130, and CESL 125).

Notably, the first etch is configured to etch through the etch stop layer (e.g., CESL 125) to expose side surfaces of the etch stop layer. The exposed side surfaces are to be later treated by a plasma treatment process 300. Note that the first etch is designed to completely etch through the etch stop layer to maximize the exposed side surface area of the etch stop layer. However, the first etch is also designed to not over-etch into the first ILD layer (e.g., ILD layer 120). Due to different materials of the etch stop layer and the first ILD layer, over-etching into the first ILD layer may cause undesired lateral etching or bowing effects to the etch stop layer. For example, the first etch may etch the etch stop layer at a faster rate than the first and second ILD layers, causing the undesired lateral etching. If this happens, the later-filled metal via in the first trench 163 may cause leakage effects with surrounding metals. As such, the first etch may sometimes under-etch slightly as long as enough of the side surfaces of the etch stop layer is exposed. In an embodiment, the first etch penetrates 90% to 100% of the thickness of the etch stop layer.

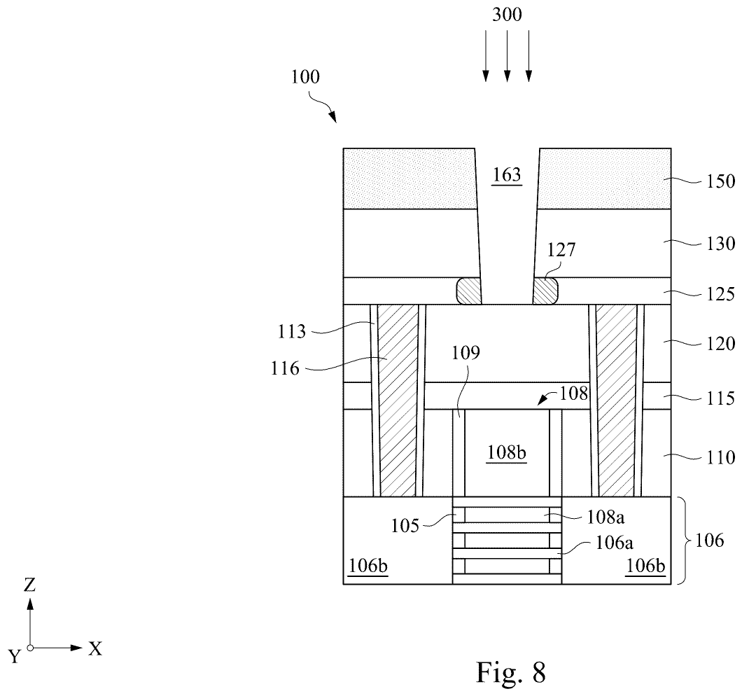

Now referring to FIG. 8, the method 1000 at operation 1016 performs a plasma treatment 300 (or plasma treatment process 300) on exposed side surfaces of the etch stop layer (e.g., CESL 125) in the first trench 163, thereby forming a modified etch stop layer 127 (also herein referred to as a modification layer 127). The plasma treatment 300 includes a plasma ashing process that applies oxygen plasma, where the plasma ashing process modifies the exposed side surfaces of the etch stop layer to form the modification layer 127. Further, the plasma ashing process simultaneously etches away the remaining portions of the etch mask (i.e., bottom layer 160c). For example, the oxygen plasma may remove all traces of organic matter, thereby removing any remaining portions of the photoresist structure 160, while at the same time introducing oxygen onto the exposed surfaces of the first trench 163. After the plasma treatment 300, sidewall portions of the exposed etch stop layer is oxygenated to form the modification layer 127. In embodiments where the etch stop layer is made of silicon nitride (SiN), the formed modification layer 127 is now formed of silicon oxynitride (SiON). And in embodiments where the etch stop layer is made of silicon carbonitride (SiCN), the formed modification layer 127 is now formed of silicon oxycarbonitride (SiOCN). In any case, the modification layer 127 includes a greater oxygen concentration than the remaining portions of the etch stop layer (e.g., unmodified portions of the CESL 125). The modification layer 127 provides a buffer protection in preparation for a later performed second etch. Specifically, the increased oxygen concentration in the modification layer 127 prevents lateral etching in the etch stop layer. In an embodiment, the oxygen concentration in the modification layer 127 is greater in the modification layer 127 than in the remaining portions of the etch stop layer by 3 to 5 times. If it is less than 3 times, there may not be enough oxygen to provide the protection of lateral over-etch. However, if it is greater than 5 times, there is no added benefit; further, there may be risk of oxidizing other unintended layers (e.g., the ILD layer 130, the hard mask layer 150, or other surrounding features). Note that since the second ILD layer (e.g., ILD layer 130) may be an oxide-based dielectric, there is less risk of any unintended oxidation of the second ILD layer. Note also that since the hard mask layer 150 may be a high density layer (e.g., due to having no or less carbon), there is also reduced risk of unintended oxidation. Therefore, as long as the oxygen levels introduced are not excessive, only the sidewalls of the etch stop layer (e.g., CESL 125) are modified and not the hard mask layer 150 and/or the second ILD layer (e.g., ILD layer 130). Further, due to the etch stop layer (e.g., CESL 125) being less dense in some embodiments, more oxygen may be absorbed into its sidewalls. For example, in embodiments where the etch stop layer includes SiCN, the plasma treatment 300 may remove some of the carbon in the etch stop layer and replace it with oxygen.

Optionally, the plasma ashing process may further apply hydrogen plasma, thereby introducing hydrogen into the modification layer 127. The hydrogen plasma may further prevent the hard mask layer 150 from unwanted oxidization. Note that the hydrogen does not prevent oxidation in the etch stop layer because the etch stop layer is a lower density layer while the hard mask layer 150 is a higher density layer (although both may include similar materials such as silicon nitride). In an embodiment, the plasma treatment 300 is performed at a chamber pressure of 1 torr where oxygen is introduced at a gas flow rate of about 6150 sccm (standard cubic centimeters per minute) and hydrogen is optionally introduced at a gas flow rate of about 1850 sccm. Carrier gases commonly used such as argon or other inert gases for preventing oxidation are not used since the plasma ashing process is intended to introduce oxygen. In an embodiment, the plasma ashing process is also free of introducing nitrogen plasma.

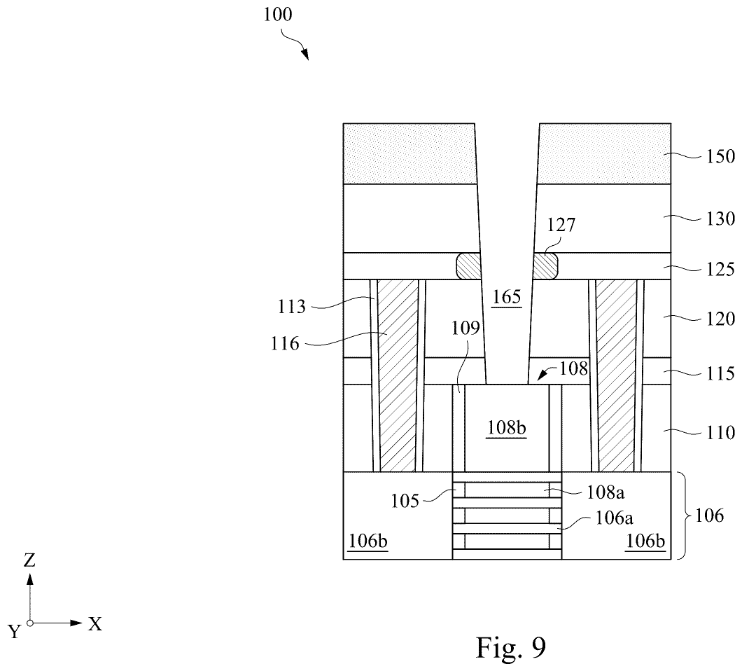

Now referring to FIG. 9, the method 1000 at operation 1018 performs a second etch to deepen the first trench 163 and thereby forming a second trench 165 that further penetrates through the first ILD layer (e.g., ILD layer 120 or collectively the ILD layer 120 plus the CESL 115). The second etch exposes a top surface of the gate structure 108. Note that since the bottom layer 160c that previously acted an etch mask is removed during the plasma treatment process 300, the hard mask layer 150 now act as a second etch mask when forming the second trench 165. Due to the now-formed modification layer 127, there will be no damage or lateral over-etch to the etch stop layer (e.g., CESL 125) when performing the second etch to deepen the first trench 163. Further, a more consistent etch profile may result due to the ILD layers 120 and 130 plus the modification layer 127 all having oxygen (e.g., SiO₂ for the ILD layers 120 and 130 and SiON for the modification layer 127).

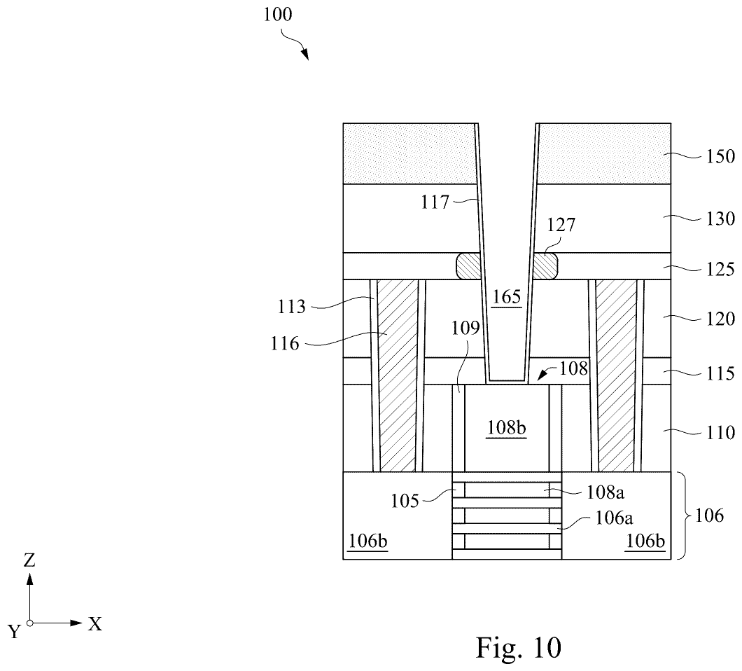

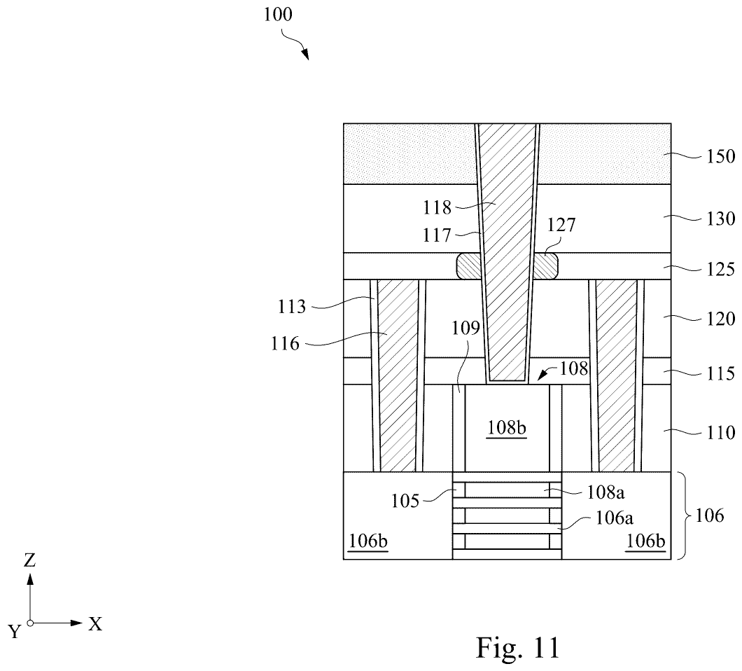

Now referring to FIGS. 10-11, the method 1000 at operation 1020 forms a gate via 118 in the second trench 165. In the embodiment shown, forming the gate via 118 includes first forming a conformal seed layer 117 in the second trench 165 (FIG. 10) then filling the rest of the trench with a metal fill. The gate via 118 may be formed through any suitable deposition process described herein.

Additional operations can be provided before, during, and after method 1000, and some of the operations described can be moved, replaced, or eliminated for additional embodiments of method 1000. For example, the method 1000 may further include forming S/D vias 126 that penetrates through the hard mask layer 150, the second ILD layer (e.g., ILD layer 130), and etch stop layer (e.g., CESL 125) to land on the S/D contacts 116 (see FIG. 12). Note that no modification layers 127 are formed in preparation of forming the S/D vias 126. In other words, the modification layer 127 are selectively formed in preparation of forming the gate vias 118 but not for the S/D vias 126. As explained herein, the modification layer 127 may not be necessary for S/D vias 126.

Further, in some embodiments, the method 1000 may further include a planarization process that planarizes the workpiece until the hard mask layer 150 is removed. Then, additional metal features and/or dielectric layers may be formed thereover to complete the semiconductor device 100. In other embodiments, the hard mask layer 150 remains, and the method 1000 includes forming additional metal features and/or dielectric layers over the hard mask layer 150 to complete the semiconductor device 100.

FIG. 12 illustrates a semiconductor device 200 having modified etch stop layers 127 surrounding gate via(s) 118 and surrounding butted contact(s) 138, according to an embodiment of the present disclosure. The semiconductor device 200 include similar features as the semiconductor device 100 described with respect to FIG. 1. As shown, the semiconductor device 200 may substantially encompass the semiconductor device 100 previously described. As such, some of the same or similar features will not be described again for the sake of brevity while some of the same or similar features are further described with additional details.

The difference of semiconductor device 200 from semiconductor device 100 is in the extension of the active region 106 to further include a butted contact 138 over a different transistor region and the inclusion of an S/D via 126 over the S/D contact 116. While FIG. 12 shows certain amounts of S/D contact(s) 116, S/D via(s) 126, gate via(s) 118, and butted contact(s) 138 over certain amounts of gate structures 108 and the active region 106; the number of these features is not limited to what is shown in FIG. 12. More or less of these features is possible without departing from the spirit and scope of the present invention.

As shown in FIG. 12, the semiconductor device 200 includes various dielectric layers previously described. The ILD layer 110 has a thickness t1, the CESL 115 plus the ILD layer 120 has a total thickness t2, the CESL 125 has a thickness t3, the ILD layer 130 has a thickness t4, and the hard mask layer 150 has a thickness t5. In an embodiment, the thickness t1 may range between about 5 to about 30 nm and correspond to the height of the top portion 108b of the gate structures 108. In an embodiment, the thickness t2 may range between about 10 nm to about 25 nm, where the thickness of the ILD layer 120 is greater than the thickness of the CESL 115. In an embodiment, the thickness t3 of the CESL 125 may range between about 2 to about 12 nm. In an embodiment, the CESL 115 also has the thickness t3. In an embodiment, the thickness t4 of the ILD layer 130 may range between about 0 to about 20 nm. In an embodiment, the ILD layer 120 also has the thickness t4. In an embodiment, the thickness t5 of the hard mask layer 150 may range between about 1 to about 40 nm.

Still referring to FIG. 12, S/D contacts 116 penetrate through the ILD layer 120, the CESL 115, and the ILD layer 110 to land on the S/D epitaxial features 106b. The S/D contacts 116 have a height equal to the sum of the thicknesses t1 and t2. S/D vias 126 penetrate through the hard mask layer 150, the ILD layer 130, and the CESL 125 to land on the S/D contacts 116. The S/D vias 126 have a height equal to the sum of the thicknesses t3, t4, and t5. The S/D vias 126 may be free of any conformal seed layers. Gate vias 118 penetrate through the hard mask layer 150, the ILD layer 130, the CESL 125, the ILD layer 120, and the CESL 115 to land on the gate structures 108. The gate vias 118 have a height equal to the sum of the thicknesses t2, t3, t4, and t5. The gate vias 118 may include conformal seed layers 117. Butted contacts 138 penetrate through the hard mask layer 150, the ILD layer 130, the CESL 125, the ILD layer 120, and the CESL 115 to have gate via portions that land on the gate structures 108 and S/D via portions that land on the S/D contacts 116. The butted contacts 138 have a height equal to the sum of the thicknesses t2, t3, t4, and t5 for the gate via portions and a height equal to the sum of the thicknesses t3, t4, and t5 for the S/D via portions. The butted contacts 138 may also have a dip portion between the gate via portion and the S/D via portion that partially penetrates the ILD layer 120. The butted contacts 138 may include conformal seed layers 137. Note that in embodiments where the hard mask layer 150 is removed, the thickness t5 is respectively subtracted for the respective heights of the S/D vias 126, the gate vias 118, and the butted contacts 138.

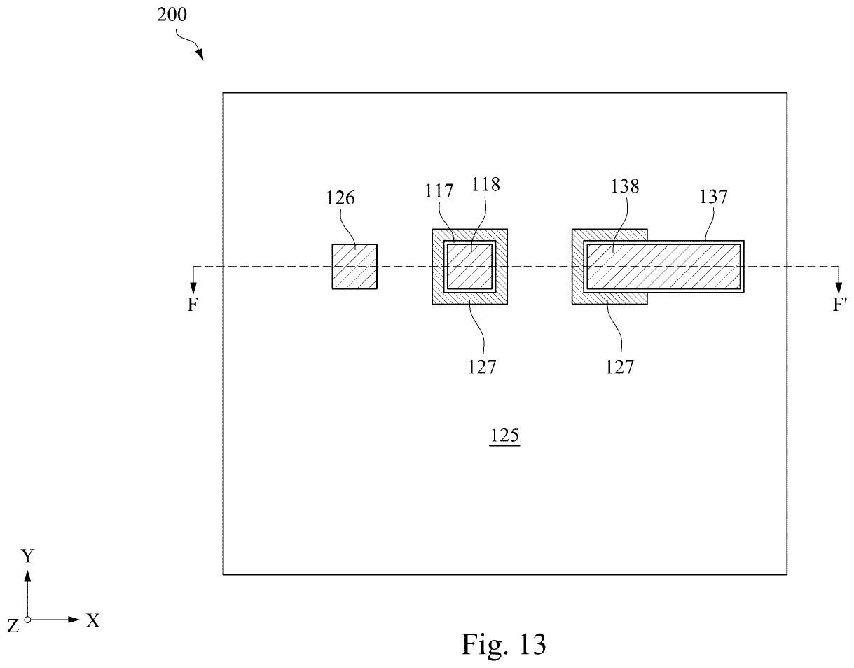

Still referring to FIG. 12, the CESL 125 includes modification layers 127 that surround the gate vias 118 and directly contact both sidewalls of the gate vias 118 when viewed along the X direction and along the Y direction (shown in FIG. 13). The CESL 125 may further include modification layers 127 that surround the butted contacts 138 and directly contact the sidewall of the gate via portion of the butted contacts 138 but not the S/D via portion of the butted contacts 138. The modification layers 127 may be selectively formed for gate vias 118 and gate via portions of the butted contacts 138 but not for the S/D vias 126 and the S/D via portions of the butted contacts. This is because there is less lateral over-etch issues when forming S/D vias 126 and S/D via portions when compared to forming gate vias 118 and gate via portions because unlike gate vias 118 and gate via portions, S/D vias 126 and S/D via portions require a smaller etch depth and does not require etching through the ILD layer 120 and the CESL 115. As such, the modified etch stop layers 127 may not be necessary for the S/D vias 126 and the S/D via portions. By selectively forming the modified etch stop layers 127 to target the gate vias or gate via portions, leakage issues are addressed while avoiding the extra costs of forming unnecessary layers.

Still referring to FIG. 12, the modification layer 127 for a gate via 118 has a width d1 extending from a sidewall of the gate via 118. In an embodiment, the width d1 ranges between about 0.1 nm to about 15 nm in the X or Y directions. In an embodiment, the width d1 should be greater than about 4 nm to achieve barrier effect during etching. The oxygen concentration of the modification layer 127 is stronger closer to the gate via 118 than radially outwards from the gate via 118. The oxygen concentration may start to decay radially by 0.1% to 20% per nm starting at a distance 0.1 nm to about 0.5 nm away from the gate via 118. The modification layer 127 may have sloped or rounded corners and form an angle θ between a horizontal surface and a sloped corner of the modification layer 127. In an embodiment, the angle θ ranges between about 5 to about 45 degrees.

Still referring to FIG. 12, the S/D vias 126 are surrounded by unmodified portions of the CESL 125 where the unmodified portions directly contact both sidewalls of the S/D vias 126 when viewed along the X direction and along the Y direction (shown in FIG. 13). In an embodiment, a distance d2 of an unmodified portion of the CESL 125 laterally between a modification layer 127 and an S/D via 126 (or S/D contact 116) ranges between about 27 nm to about 200 nm. In an embodiment, a vertical distance d3 between a modification layer 127 and a gate structure 108 is equal to the thickness t2. In an embodiment, a horizontal distance d4 between adjacent gate vias 118 ranges between about 35 nm to about 800 nm, and a horizontal distance d5 between a gate via 118 and an adjacent butted contact 138 ranges between about 35 nm to about 200 nm.

FIG. 13 illustrates a top view of a semiconductor device 200 having modified etch stop layers 127 (also referred to as modification layers 127) surrounding a gate via 118 and a butted contact 138. FIG. 13 shows one S/D via 126, one gate via 118, and one butted contact 138, but more or less of these features is possible without departing from the spirit and scope of the present invention. FIG. 13 corresponds with FIG. 12, and the top view of FIG. 13 is cut along the CESL 125 and along the line F-F′ shown in FIG. 12. As shown, the S/D vias 126 may be completely surrounded by and directly contact unmodified portions of the CESL 125 along the X and Y directions. The gate vias 118 may be completely surrounded by and directly contact the modification layers 127 along the X and Y direction. While the butted contacts 138 may only be partially surrounded by and directly contact the modification layers 127 along the X and Y direction. As shown, the modification layer 127 for a butted contact 138 only directly contacts and surrounds 3 sides of the gate via portion of the butted contact 138, while the S/D via portion of the butted contact 138 is surrounded by and directly contacts unmodified portions of the CESL 125. In this view, the modification layer 127 for gate vias 118 have an “O” shape while the modification layers 127 for butted contacts 138 have a “C” shape. Further in this view, the respective conformal seed layers 117 and 137 may directly interface with the unmodified portions of the CESL 125 and/or the modification layers 127.

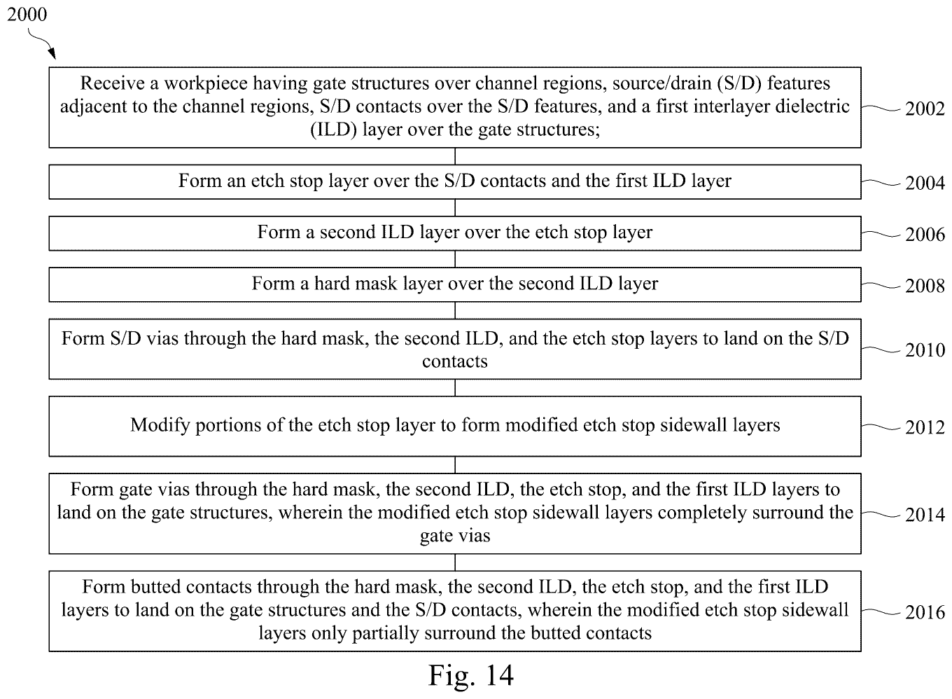

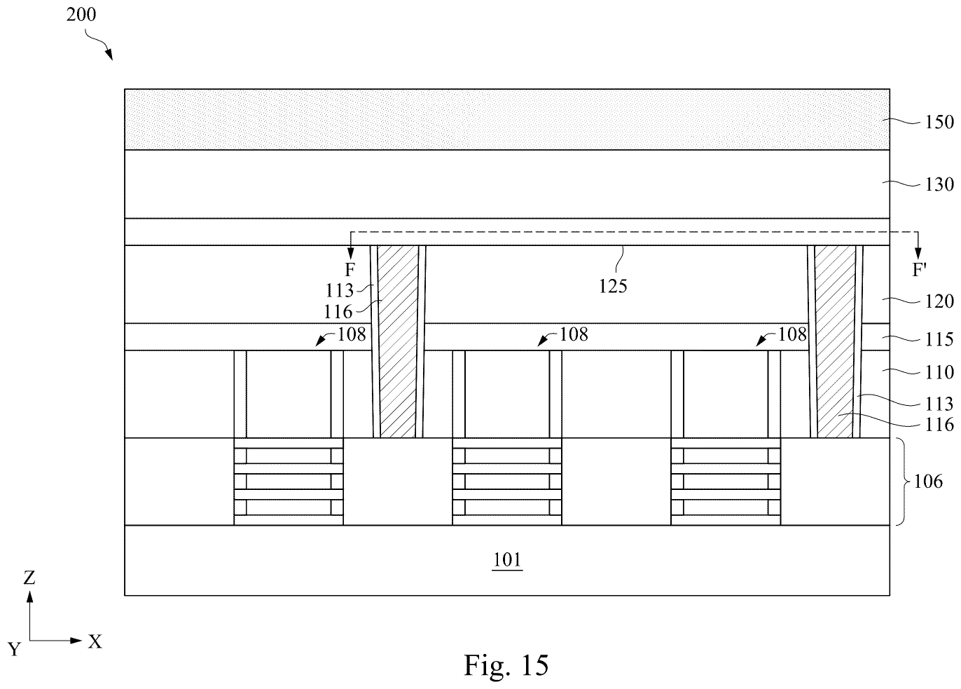

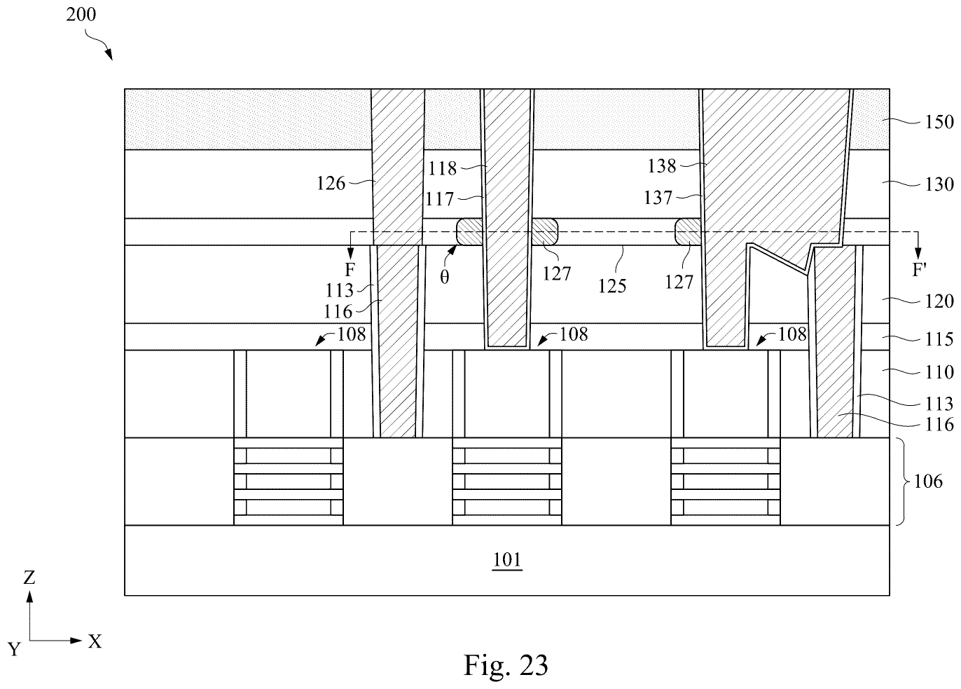

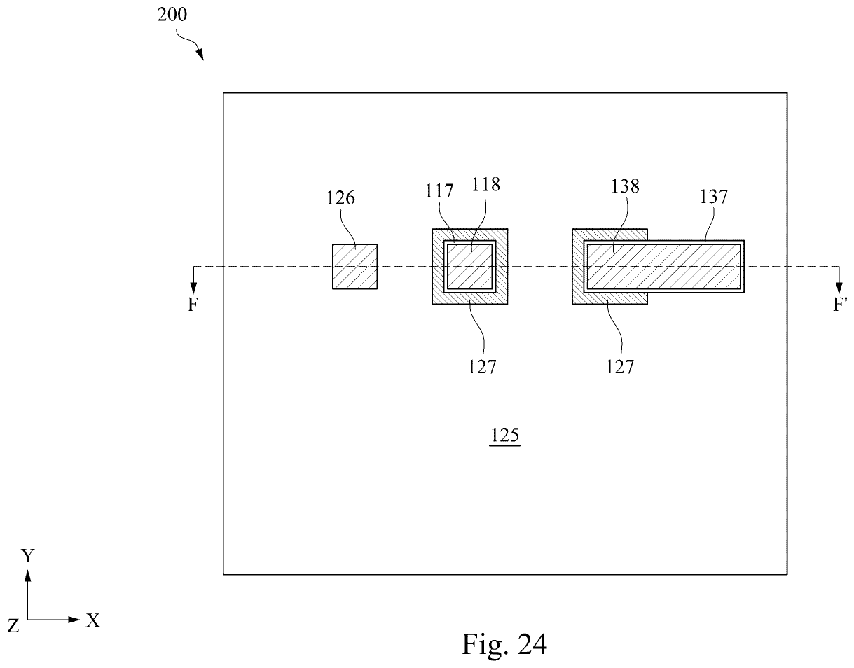

FIG. 14 illustrates a flow chart of a method 2000 to form a semiconductor device 200 having modified etch stop layers 127 surrounding a gate via 118 (or gate vias 118) and surrounding a butted contact 138 (or butted contacts 138), in portion or in entirety, according to an embodiment of the present disclosure. FIGS. 15-24 illustrate cross-sectional and top views of a semiconductor device 200 at intermediate stages of fabrication and processed in accordance with the method 2000 of FIG. 14. The method 2000 is described below with reference to FIGS. 15-24. Features described with respect to FIGS. 12 and 13 may correspond to features described with reference to FIGS. 15-24. Some of the same or similar features are further described with additional details, while some of the same or similar features are will not be described again for the sake of brevity. Further, some features and/or labels may be omitted in FIGS. 15-24 when compared to FIGS. 12 and 13 for purposes of simplification.

Referring now to FIG. 15, the method 2000 at operation 2002 receives a workpiece having gate structures 108 over channels 106a of a channel region. The workpiece further includes S/D epitaxial features 106b adjacent to the channel regions, S/D contacts 116 over the S/D epitaxial features 106b, and a first interlayer dielectric (ILD) (e.g., ILD layer 120) layer over the gate structures. The first ILD layer may refer to the ILD layer 120 or it may refer to the CESL 115 and the ILD layer 120 collectively. FIG. 15 shows two S/D contacts 116 for illustrative purposes. Other numbers of S/D contacts 116 are also possible. Operation 2002 is similar to operation 1002 previously described. As such, operation 2002 will not be described again for the sake of brevity.

Still referring to FIG. 15, the method 2000 at operation 2004 forms an etch stop layer (e.g., CESL 125) over the S/D contacts 116 and the first ILD layer (e.g., ILD layer 120). Operation 2004 is similar to operation 1004 previously described. As such, operation 2004 will not be described again for the sake of brevity.

Still referring to FIG. 15, the method 2000 at operation 2006 forms a second ILD layer (e.g., ILD layer 130) over the etch stop layer (e.g., CESL 125). Operation 2006 is similar to operation 1006 previously described. As such, operation 2006 will not be described again for the sake of brevity.

Still referring to FIG. 15, the method 2000 at operation 2008 forms a hard mask layer 150 over the second ILD layer (e.g., ILD layer 130). Operation 2008 is similar to operation 1008 previously described. As such, operation 2008 will not be described again for the sake of brevity.

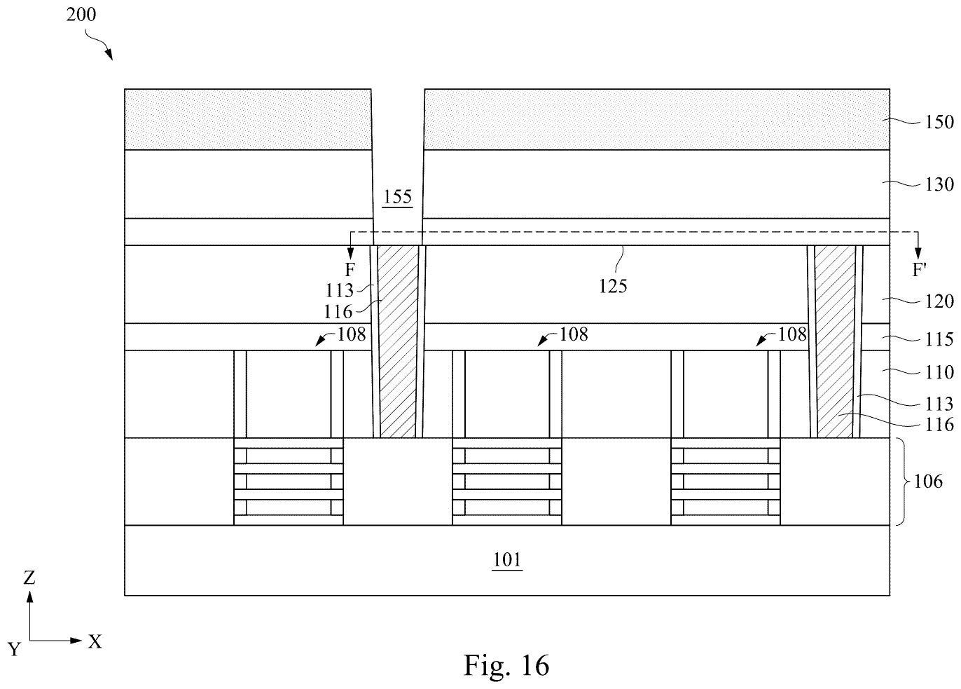

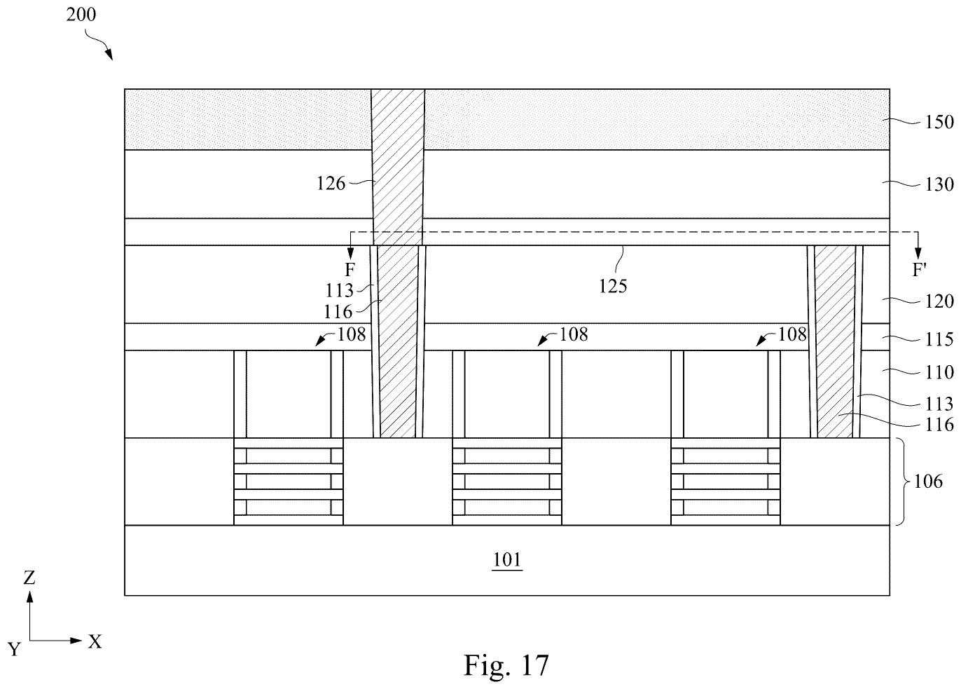

Referring now to FIGS. 16-17, the method 2000 at operation 2010 forms S/D vias 126 through the hard mask layer 150, the second ILD layer (e.g., ILD layer 130), and the etch stop layer (e.g., CESL 125) to land on the S/D contacts 116. The operation 2010 may include first forming S/D via trenches 155 (see FIG. 16) by a patterning process to expose one or more S/D contacts 116. The patterning process may include lithography and etching, where a patterned mask layer is formed over the workpiece, and the S/D via trenches 155 are formed by etching through openings defined by the patterned mask layer. Note that the patterning process does not form S/D via trenches 155 over some of the S/D contacts 116. These S/D contacts 116 will later have butted contacts 138 formed over them. After forming the S/D via trenches 155, the operation 2010 may then include forming S/D vias 126 in the S/D via trenches 155. In the present embodiment, the S/D vias 126 are formed through bottom-up metal growth without first depositing any conformal seed layers. For example, a metal fill layer is deposited directly in the S/D via trenches 155 where the metal fill is directly grown from the top surface of the S/D contacts 116. The metal fill then forms the S/D vias 126. A conformal seed layer may not be necessary due to the S/D via trenches 155 having a lower aspect ratio (e.g., as compared to gate via trenches) and that the metal materials for the S/D contacts 116 and the S/D vias 126 may be of a same material to facilitate good interface contact when performing bottom-up growth. In an embodiment, both the S/D contacts 116 and the S/D vias 126 include tungsten.

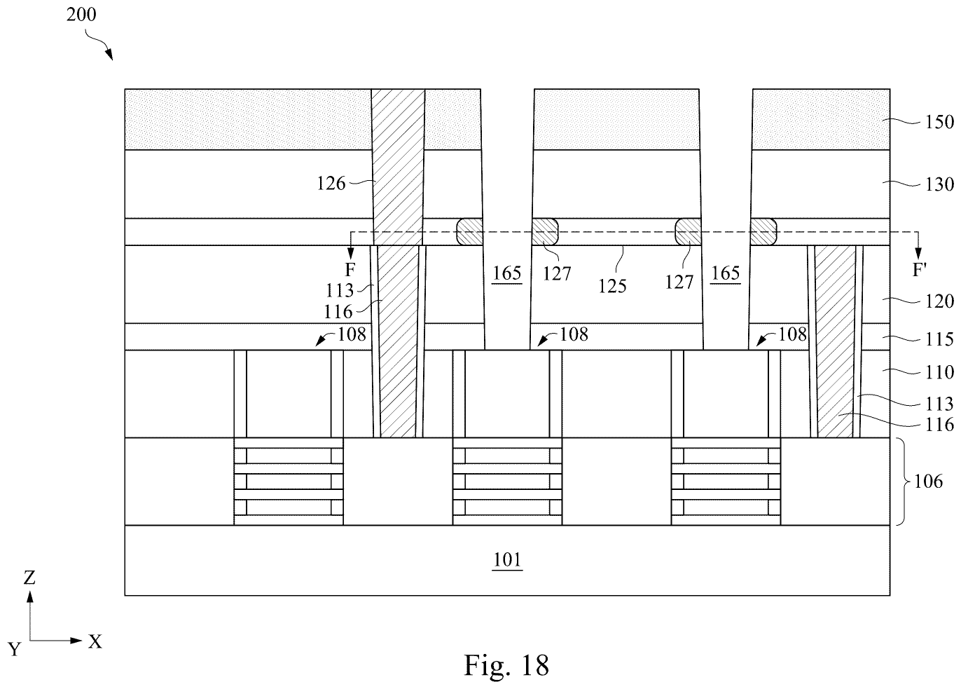

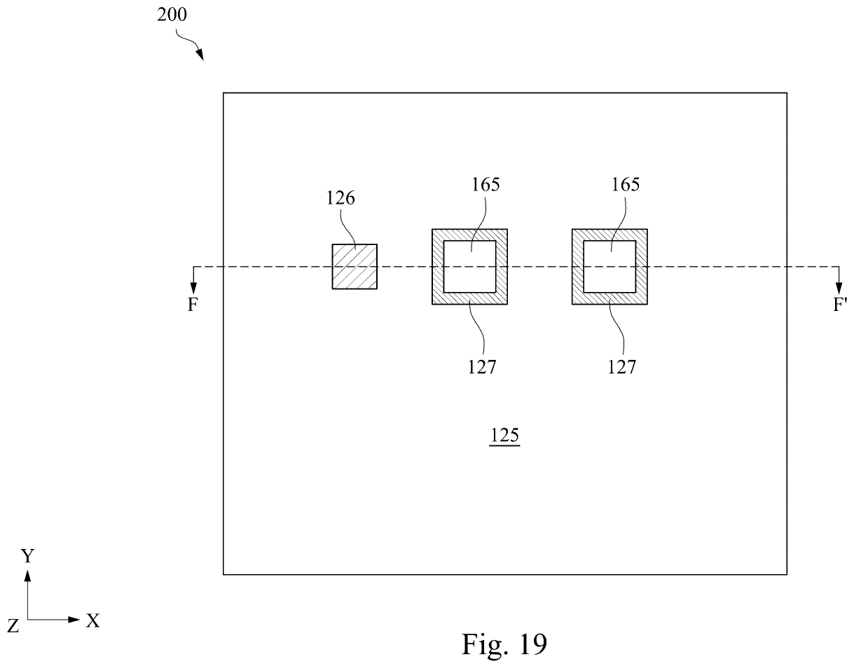

Referring now to FIGS. 18-19, the method 2000 at operation 2012 modifies portions of the etch stop layer (e.g., CESL 125) to form modified etch stop sidewall layers 127. The modified etch stop sidewall layers 127 are formed in preparation of forming gate vias 118 and/or gate via portions of the butted contacts 138. As such, the operation 2012 may also include forming gate via trenches (e.g., second trenches 165 previously described) later to be filled. Operation 2012 may be performed by operations 1010 to 1018 previously described in method 1000. As such, operation 2012 will not be described again for the sake of brevity. Turning briefly to FIG. 19, a top view of FIG. 18 along the line F-F′ and across the etch stop layer (e.g., CESL 125) is shown. At this operation step, unmodified portions of the etch stop layer (e.g., CESL 125) directly contact and completely surround the S/D vias 126, and modified portions of the etch stop layer (i.e., modified etch stop sidewall layers 127) directly contact and completely surround the gate via trenches (e.g., second trenches 165).

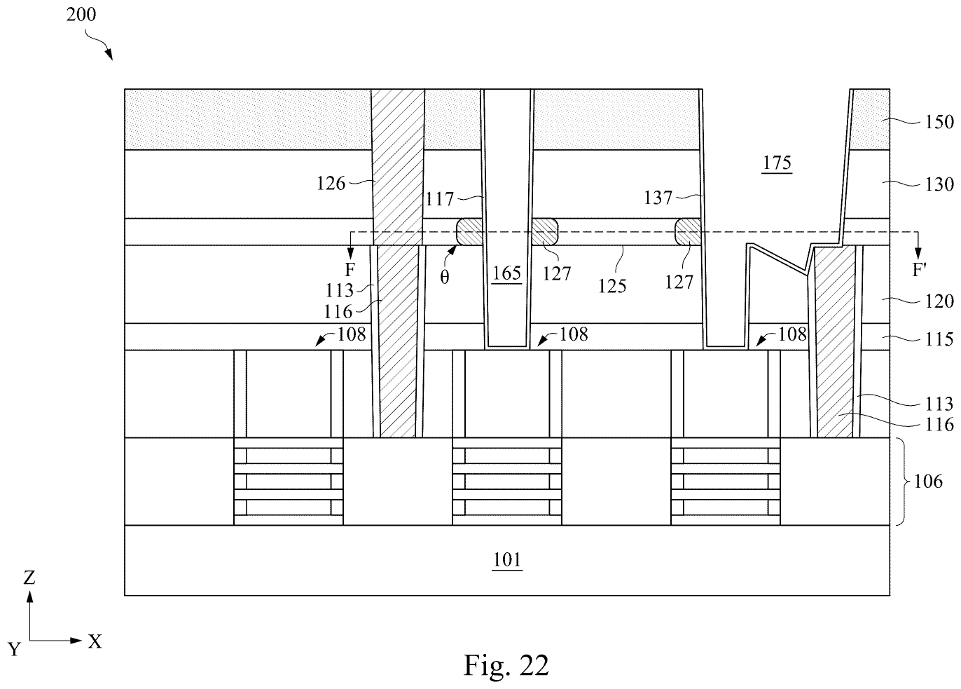

Skipping to FIGS. 22-24, the method 2000 at operation 2014 forms gate vias 118 through the hard mask layer 150, the second ILD layer (e.g., ILD layer 130), the etch stop layer (e.g., CESL 125), and the first ILD layer (e.g., ILD layer 120 or collectively the ILD layer 120 plus the CESL 115) to land on the gate structures 108, where the modified etch stop sidewall layers 127 completely surround the gate vias 118. Operation 2014 is similar to operation 1020 previously described. As such, operation 2014 will not be described again for the sake of brevity. Note that in the present embodiment, the gate vias 118 include conformal seed layers 117 to improve gate metal fill due to the gate vias' higher aspect ratio and that the gate metal fill may include different materials than the gate structure 108 it is landing on. In an embodiment, a gate structure 108 may have a top width ranging between about 9 nm to about 100 nm and a gate via 118 may have a bottom width ranging between about 8.5 to about 18 nm.

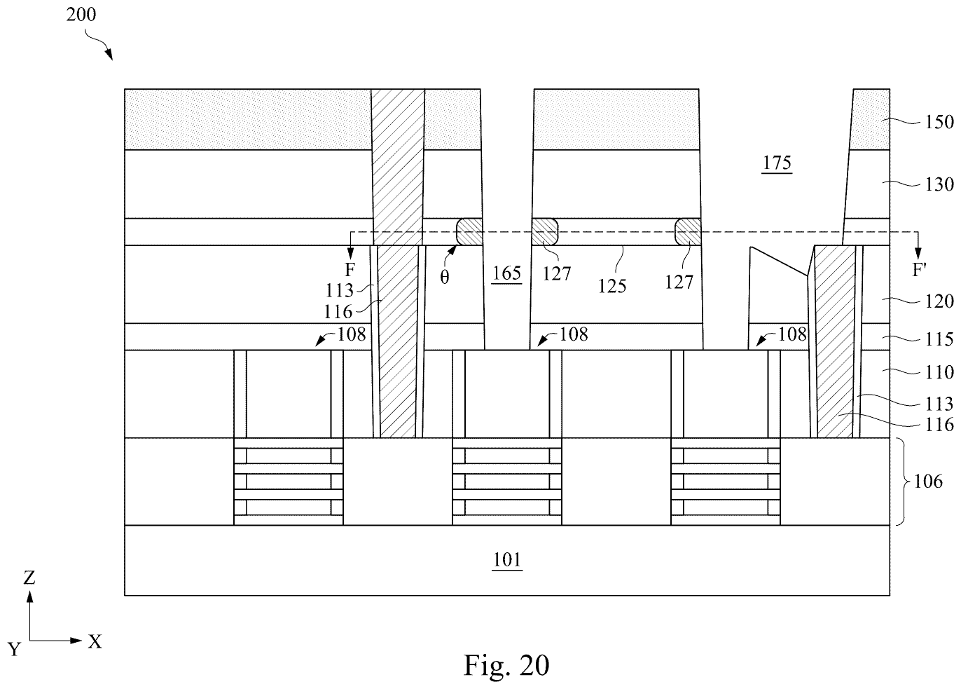

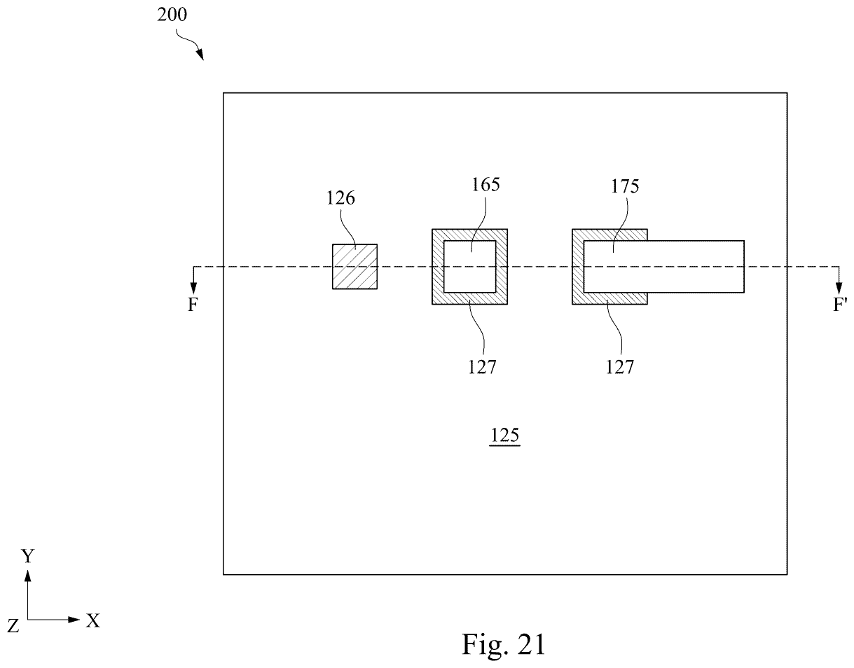

Referring back to FIGS. 20-21 and additionally to FIGS. 22-24, the method 2000 at operation 2016 forms butted contacts 138 through the hard mask layer 150, the second ILD layer (e.g., ILD layer 130), the etch stop layer (e.g., CESL 125), and the first ILD layer (e.g., ILD layer 120 or collectively the ILD layer 120 plus the CESL 115) to land on the gate structures 108 and the S/D contacts 116, where the modified etch stop sidewall layers 127 only partially surround the butted contacts 138. Referring to FIG. 20, the operation 2016 includes first widening one or more of the gate via trenches previously formed (e.g., second trenches 165) to form butted contact trenches 175. The butted contact trenches 175 may be formed by a patterning process that includes lithography and etching, where a patterned mask layer is formed over the workpiece to define S/D via portion openings adjacent the gate via trenches (e.g., second trenches 165), and the butted contact trenches 175 are formed by etching through the S/D via portion openings defined by the patterned mask layer. As a result, butted contact trenches 175 are formed to have gate via trench portions exposing gate structures 108 and S/D via trench portions exposing S/D contacts 116. Further, due to the etching to laterally extend the gate via trench portions, there may be a trench dip into the ILD layer 120 between the gate via trench portions and the S/D via trench portions. Even further, a sidewall portion of the modified etch stop sidewall layers 127 is removed when forming the butted contact trenches 175.

Turning briefly to FIG. 21, a top view of FIG. 20 along the line F-F′ and across the etch stop layer (e.g., CESL 125) is shown. At this operation step, the formed butted contact trenches 175 extend and penetrate through a sidewall of the modified etch stop sidewall layer 127. As a result, the remaining modified etch stop sidewall layer 127 hugs the gate via portion of the butted contact trenches 175 on the remaining three sides.

Next, referring now to FIGS. 22-24, a metal fill is formed in the butted contact trenches 175 by a suitable deposition process, thereby forming the butted contacts 138. In the present embodiment, the butted contacts 138 are formed simultaneously with the gate vias 118. For example, the conformal seed layers 117 for the gate vias 118 are formed together with the conformal seed layers 137 for the butted contacts, and the metal fill to fill the gate trenches (e.g., second trenches 165 are filled together with the metal fill to fill the butted contact trenches 175. In this way, the same material and process may be used to form both features to save cost. Note that like the gate vias 118, the butted contacts 138 also include seed layers for similar reasons as for the gate vias 118. For example, these seed layers are present at least due to the butted contacts 138 having gate via portions that extends to land on gate structures 108, even though the S/D via portions of the butted contacts 138 may not need the seed layers.

In the present embodiment, the gate vias 118 and the butted contacts 138 are formed after forming the S/D vias 126 but the present disclosure is not limited thereto. The gate vias 118 and the butted contacts 138 may be first formed together, then the S/D vias 126 are formed thereafter.

Additional operations can be provided before, during, and after method 2000, and some of the operations described can be moved, replaced, or eliminated for additional embodiments of method 1000. For example, the method 2000 may further include a planarization process that planarizes the workpiece until the hard mask layer 150 is removed. Then, additional metal features and/or dielectric layers may be formed thereover to complete the semiconductor device 200. In other embodiments, the hard mask layer 150 remains, and the method 2000 includes forming additional metal features and/or dielectric layers over the hard mask layer 150 to complete the semiconductor device 200.

Although not intended to be limiting, the present disclosure offers advantages related to forming gate vias in semiconductor devices. One example advantage is forming modified etch stop layers as protection layers when forming gate via trenches. These modified etch stop layers prevent lateral over-etch that may lead to gate-to-S/D leakage. Another example advantage is forming the modified etch stop layers by a plasma treatment process that simultaneously treats sidewalls of an etch stop layer and removes photoresist structures. Another example advantage is selectively forming the modified etch stop layers for gate vias and gate via portions to save cost. Another example advantage is selectively forming conformal seed layers of gate vias and gate via portions.

One aspect of the present disclosure pertains to a semiconductor device. The semiconductor device includes a source/drain (S/D) contact over an S/D feature; a gate structure over a channel region, where the channel region is adjacent the S/D feature; a first interlayer dielectric (ILD) layer over the gate structure and surrounding the S/D contact; an etch stop layer over the first ILD layer and the S/D contact, where the etch stop layer includes a first portion and a second portion, and the second portion is different from the first portion in chemical composition; a second ILD layer over the etch stop layer; and a gate via over the gate structure, where the gate via is surrounded by the second portion of the etch stop layer.

In an embodiment, both the first and the second portions of the etch stop layer include silicon nitride, but the second portion of the etch stop layer has a greater oxygen concentration than the first portion of the etch stop layer.

In an embodiment, the second portion of the etch stop layer is disposed between the gate via and the S/D contact.

In an embodiment, the first and the second portions of the etch stop layer share a common top surface and a common bottom surface.

In an embodiment, the semiconductor further includes a hard mask layer over the second ILD layer, where both the etch stop layer and the hard mask layer includes silicon nitride, but the hard mask layer has a higher density than the etch stop layer. In a further embodiment, the gate via penetrates through the hard mask layer, the second ILD layer, the etch stop layer, and the first ILD layer to land on the gate structure.

In an embodiment, the etch stop layer is a first etch stop layer, and the semiconductor device further includes a second etch stop layer between the gate structure and the first ILD layer, where the gate via further penetrates through the second etch stop layer to land on the gate structure.

In an embodiment, the semiconductor further includes an S/D via over the S/D contact, where the S/D via is surrounded by the first portion of the etch stop layer. In a further embodiment, the gate via includes a conductive seed layer surrounding a gate via fill layer, and the conductive seed layer directly contacts the second portion of the etch stop layer. In a further embodiment, the S/D via includes an S/D via metal fill layer, and the S/D via metal fill layer directly contacts the first portion of the etch stop layer.

Another aspect of the present disclosure pertains to a semiconductor device. The semiconductor device includes gate structures over channel regions of a substrate; source/drain (S/D) features adjacent the channel regions; a first interlayer dielectric (ILD) layer over the gate structures and the S/D features; S/D contacts penetrating through the first ILD layer to land on the S/D features; an etch stop layer over the first ILD layer and the S/D contacts, where the etch stop layer includes a first portion and a second portion, and the second portion is different from the first portion in chemical composition; a second ILD layer over the etch stop layer; S/D vias penetrating through the second ILD layer and the first portion of the etch stop layer to land on the S/D contacts; and gate vias penetrating through the second ILD layer, the second portion of the etch stop layer, and the first ILD layer to land on the gate structure.

In an embodiment, the second portion of the etch stop layer has a greater oxygen concentration than the first portion of the etch stop layer.

In an embodiment, the semiconductor further includes a hard mask layer over the second ILD layer, where the hard mask layer includes different materials from the second ILD layer, where each of the S/D vias and the gate vias further penetrates through the hard mask layer.

In an embodiment, the S/D vias directly contact and are completely surrounded by the first portion of the etch stop layer.

In an embodiment, the gate vias directly contact and are completely surrounded by the second portion of the etch stop layer.

In an embodiment, the S/D vias land on first S/D contacts of the S/D contacts, the gate vias land on first gate structures of gate structures, and the semiconductor device further includes: butted contacts penetrating through the second ILD layer, the first and the second portions of the etch stop layer, and the first ILD layer, where each of the butted contacts simultaneously lands on a second S/D contact of the S/D contacts and a second gate structure of the gate structures.

In a further embodiment, the butted contacts directly contact and are partially surrounded by the first portion of the etch stop layer, and the butted contacts directly contact and are partially surrounded by the second portion of the etch stop layer.

Another aspect of the present disclosure pertains to a method of forming a semiconductor device. The method includes receiving a workpiece having a gate structure over a channel region, a source/drain (S/D) feature adjacent to the channel region, and a first interlayer dielectric (ILD) layer directly over the S/D feature, and a second ILD layer directly over the first ILD layer and directly over the gate structure; forming an S/D contact through the first and the second ILD layers to land on a top surface of the S/D feature; forming an etch stop layer over the second ILD layer and over the S/D contact; forming a third ILD layer over the etch stop layer; forming a hard mask layer over the third ILD layer; patterning a photoresist structure to form an etch mask over the hard mask layer; performing a first etch using the etch mask to form a first trench through the hard mask layer, the third ILD layer, and the etch stop layer to expose a top surface of the second ILD layer; performing a plasma treatment on exposed side surfaces of the etch stop layer in the first trench, thereby forming a modification layer; performing a second etch to deepen the first trench and thereby forming a second trench that further penetrates through the second ILD layer to expose a top surface of the gate structure; and forming a gate via in the second trench.

In an embodiment, the plasma treatment includes a plasma ashing process that applies oxygen plasma, where performing the plasma ashing process simultaneously etches away the etch mask and modifies the exposed side surfaces of the etch stop layers to form the modification layer.

In an embodiment, the plasma ashing process further applies hydrogen plasma.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor device, comprising:
a source/drain (S/D) contact over an S/D feature;
a gate structure over a channel region, wherein the channel region is adjacent the S/D feature;
a first interlayer dielectric (ILD) layer over the gate structure and surrounding the S/D contact;
an etch stop layer over the first ILD layer and the S/D contact, wherein the etch stop layer includes a first portion and a second portion, and the second portion is different from the first portion in chemical composition;
a second ILD layer over the etch stop layer; and
a gate via over the gate structure, wherein the gate via is surrounded by the second portion of the etch stop layer.

2. The semiconductor device of claim 1, wherein both the first and the second portions of the etch stop layer include silicon nitride, but the second portion of the etch stop layer has a greater oxygen concentration than the first portion of the etch stop layer.

3. The semiconductor device of claim 1, wherein the second portion of the etch stop layer is disposed between the gate via and the S/D contact.

4. The semiconductor device of claim 1, wherein the first and the second portions of the etch stop layer share a common top surface and a common bottom surface.

5. The semiconductor device of claim 1, further comprising:
a hard mask layer over the second ILD layer, wherein both the etch stop layer and the hard mask layer includes silicon nitride, but the hard mask layer has a higher density than the etch stop layer.

6. The semiconductor device of claim 5, wherein the gate via penetrates through the hard mask layer, the second ILD layer, the etch stop layer, and the first ILD layer to land on the gate structure.

7. The semiconductor device of claim 1, wherein the etch stop layer is a first etch stop layer, further comprising:
a second etch stop layer between the gate structure and the first ILD layer, wherein the gate via further penetrates through the second etch stop layer to land on the gate structure.

8. The semiconductor device of claim 1, further comprising:
an S/D via over the S/D contact, wherein the S/D via is surrounded by the first portion of the etch stop layer.

9. The semiconductor device of claim 8, wherein the gate via includes a conductive seed layer surrounding a gate via fill layer, and the conductive seed layer directly contacts the second portion of the etch stop layer.

10. The semiconductor device of claim 9, wherein the S/D via includes an S/D via metal fill layer, and the S/D via metal fill layer directly contacts the first portion of the etch stop layer.

11. A semiconductor device, comprising:
gate structures over channel regions of a substrate;
source/drain (S/D) features adjacent the channel regions;
a first interlayer dielectric (ILD) layer over the gate structures and the S/D features;
S/D contacts penetrating through the first ILD layer to land on the S/D features;
an etch stop layer over the first ILD layer and the S/D contacts, wherein the etch stop layer includes a first portion and a second portion, and the second portion is different from the first portion in chemical composition;
a second ILD layer over the etch stop layer;
S/D vias penetrating through the second ILD layer and the first portion of the etch stop layer to land on the S/D contacts; and
gate vias penetrating through the second ILD layer, the second portion of the etch stop layer, and the first ILD layer to land on the gate structure.

12. The semiconductor device of claim 11, wherein the second portion of the etch stop layer has a greater oxygen concentration than the first portion of the etch stop layer.

13. The semiconductor device of claim 11, further comprising:
a hard mask layer over the second ILD layer, wherein the hard mask layer includes different materials from the second ILD layer,
wherein each of the S/D vias and the gate vias further penetrates through the hard mask layer.

14. The semiconductor device of claim 11, wherein the S/D vias directly contact and are completely surrounded by the first portion of the etch stop layer.

15. The semiconductor device of claim 11, wherein the gate vias directly contact and are completely surrounded by the second portion of the etch stop layer.

16. The semiconductor device of claim 11, wherein the S/D vias land on first S/D contacts of the S/D contacts, the gate vias land on first gate structures of gate structures, further comprising:
butted contacts penetrating through the second ILD layer, the first and the second portions of the etch stop layer, and the first ILD layer, wherein each of the butted contacts simultaneously lands on a second S/D contact of the S/D contacts and a second gate structure of the gate structures.

17. The semiconductor device of claim 16,
wherein the butted contacts directly contact and are partially surrounded by the first portion of the etch stop layer,
wherein the butted contacts directly contact and are partially surrounded by the second portion of the etch stop layer.

18. A method of forming a semiconductor device, comprising:
receiving a workpiece having a gate structure over a channel region, a source/drain (S/D) feature adjacent to the channel region, and a first interlayer dielectric (ILD) layer directly over the S/D feature, and a second ILD layer directly over the first ILD layer and directly over the gate structure;
forming an S/D contact through the first and the second ILD layers to land on a top surface of the S/D feature;
forming an etch stop layer over the second ILD layer and over the S/D contact;
forming a third ILD layer over the etch stop layer;
forming a hard mask layer over the third ILD layer;
patterning a photoresist structure to form an etch mask over the hard mask layer;
performing a first etch using the etch mask to form a first trench through the hard mask layer, the third ILD layer, and the etch stop layer to expose a top surface of the second ILD layer;
performing a plasma treatment on exposed side surfaces of the etch stop layer in the first trench, thereby forming a modification layer;
performing a second etch to deepen the first trench and thereby forming a second trench that further penetrates through the second ILD layer to expose a top surface of the gate structure; and
forming a gate via in the second trench.

19. The method of claim 18, wherein the plasma treatment includes a plasma ashing process that applies oxygen plasma, wherein performing the plasma ashing process simultaneously etches away the etch mask and modifies the exposed side surfaces of the etch stop layers to form the modification layer.

20. The method of claim 18, wherein the plasma ashing process further applies hydrogen plasma.
